(19) United States
(12) Patent Application Publication
(10) Pub. No.: US 2014/0068374 A1
(43) Pub. Date: Mar. 6, 2014

(54) DISPLAY DEVICE AND METHOD OF DETECTING ERROR THEREIN

(71) Applicants: Seong Keun HA, Yongin-City (KR); Wook LEE, Yongin-City (KR)

(72) Inventors: Seong Keun HA, Yongin-City (KR); Wook LEE, Yongin-City (KR)

(21) Appl. No.: 13/944,083

(22) Filed: Jul. 17, 2013

(30) Foreign Application Priority Data
Aug. 29, 2012 (KR) 10-2012-0095162

(51) Int. Cl. H03M 13/29

(52) U.S. Cl. CPC H03M 13/2909
USPC 714/755

(57) ABSTRACT

A method of detecting an error in a display device including a memory and a driving IC on which the memory is arranged is disclosed. The method includes receiving display data and a first error correction code of the display data from an outside, generating a second error correction code based on the received display data, comparing the received first error correction code with the generated second error correction code to provide a first comparison result, and detecting the error based on the first comparison result.

### CROSS-REFERENCE TO RELATED APPLICATION

This application is based on and claims priority under 35 U.S.C. §119 from Korean Patent Application No. 10-2012-0095162, filed on Aug. 29, 2012 in the Korean Intellectual Property Office, the disclosure of which is incorporated herein in its entirety by reference.

### BACKGROUND

1. Field

Embodiments relate to a display device and a method of detecting an error in the display device, and more particularly to a display device and a method of detecting an error in the display device.

2. Description of the Prior Art

Display devices, in particular, liquid crystal display devices, have the characteristics of small size, light weight, and low power consumption, and have been adopted and used in not only small-sized devices such as mobile phones, personal digital assistants (PDAs), portable multimedia players (PMPs), and the like, but also middle or large-sized devices, such as monitors, TVs, and the like.

Such a display device includes a memory in which data for displaying an image is stored. In general, in order to detect whether the data stored in the memory has been properly stored, that is, whether an error exists in the data, all data stored in the memory is read. However, in the case of reading all data stored in the memory, a considerable loss of time occurs.

### SUMMARY

According to one or more embodiments, a method of detecting an error in a display device including a memory and a driving IC on which the memory is arranged, including receiving display data and a first error correction code of the display data from an outside, generating a second error correction code based on the received display data, comparing the received first error correction code with the generated second error correction code to provide a first comparison result, and detecting the error based on the first comparison result.

The method may further include, before receiving display data and the first error correction code, confirming numerical data stored in the memory, changing the numerical data stored in the memory, after providing the first comparison result, and comparing the numerical data stored in the memory with the confirmed numerical data to provide a second comparison result, wherein detecting detects the error is based on the second comparison result.

The method may further include repeating receiving to changing at least once after the changing step.

The method may further include receiving a third error correction code of the display data after the first detection step and storing the display data and the third error correction code in the memory, loading the display data stored in the memory and generating a fourth error correction code based on the loaded display data, and comparing the third error correction code with the fourth error correction code to generate a third comparison result, and detecting the error based on the third comparison result.

According to one or more embodiments, a method of detecting an error in a display device including a memory and a driving IC on which the memory is arranged, may include storing display data and a first CRC (Cycle Redundancy Checking) code of the display data in the memory, loading the display data stored in the memory and generating a second CRC code of the display data, comparing the first CRC code with the second CRC code to provide a first comparison result, and detecting the error based on the first comparison result.

The display device may include a display panel, and the display data may be data that is used to display an image or a picture on the display panel.

Generating may include generating the second CRC code in an inside of the driving IC.

Comparing may include comparing the first CRC code with the second CRC code in an inside of the driving IC.

Comparing may include inscribing the result of the comparison of the first CRC code with the second CRC code in an error inscription register as an error flag.

The error inscription register may be included in the memory.

Detecting may include confirming the error flag in the error inscription register.

The memory may be an OTP (One Time Programmable) memory or an MTP (Multi Time Programmable) memory.

According to one or more embodiments, there is provided a display device comprising a memory and a driving IC on which the memory is arranged, wherein the driving IC is configured to receive display data and a first error correction code of the display data from an outside, generate a second error correction code based on the received display data, compare the received first error correction code with the generated second error correction code to provide a first comparison result, and detect an error based on the first comparison result.

The numerical data may be stored in the memory, and the driving IC may be configured to change the numerical data stored in the memory based on the first comparison result, compare the numerical data stored in the memory before receiving the display data with the numerical data changed on the basis of the first comparison result, and detect the error based on the result of the comparison of the numerical data.

According to one or more embodiments, a display device includes a memory and a driving IC on which the memory is arranged, wherein display data and a first CRC (Cycle Redundancy Checking) code of the display data are stored in the memory, and the driving IC is configured to load the display data stored in the memory, generate a second CRC code of the display data, compare the first CRC code with the second CRC code, and detects the error based on the result of the comparison.

The display device may further include a display panel, wherein the display data is data that is used to display an image or a picture on the display panel.

The driving IC may inscribe the result of the comparison of the first CRC code with the second CRC code in an error inscription register as an error flag.

The error inscription register may be included in the memory.

The driving IC may detect the error by confirming the error flag in the error inscription register.

### BRIEF DESCRIPTION OF THE DRAWINGS

The above and other features and advantages will be more apparent from the following detailed description taken in conjunction with the accompanying drawings, in which:

FIG. 1 is a conceptual view of a display device according to an embodiment;

FIG. 2 is a conceptual view of a driving IC of a display device according to an embodiment;

FIG. 3 is a flowchart illustrating a method of detecting an error in a display device according to an embodiment; and

FIG. 4 is a flowchart illustrating a method of detecting an error in a display device according to an embodiment.

### DETAILED DESCRIPTION

Advantages and features of embodiments and methods of accomplishing the same may be understood more readily by reference to the following detailed description of preferred embodiments and the accompanying drawings. The embodiments may, however, be embodied in many different forms and should not be construed as being limited to the embodiments set forth herein. Rather, these embodiments are provided so that this disclosure will be thorough and complete and will fully convey the concept of to those skilled in the art, and the present invention will only be defined by the appended claims. Thus, in some embodiments, well-known structures and devices are not shown in order not to obscure the description of the embodiments with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views. Accordingly, the exemplary views may be modified depending on manufacturing technologies and/or tolerances. Therefore, the embodiments are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects thereof.

Hereinafter, embodiments will be described in detail with reference to the accompanying drawings.

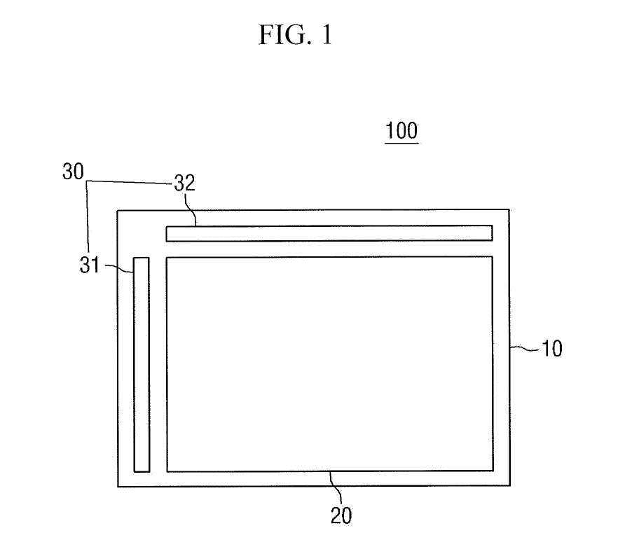

FIG. 1 is a conceptual view of a display device according to an embodiment. Referring to FIG. 1, a display device 100 may include a substrate 10, a display panel 20, and a driving IC 30.

The display panel 20 may be arranged on the substrate 10. The substrate 10 may be a base substrate which is made of an insulating material to support the display panel 20. In some embodiments, the substrate 10 may be made of an insulating material, such as glass or plastic.

The display panel 20 may be a panel that displays an image, and may be an LCD panel (Liquid Crystal Display panel), an electrophoretic display panel, an OLED panel (Organic Light Emitting Diode Panel), an LED panel, an inorganic EL panel (Electro Luminescent display panel), an FED panel (Field Emission Display panel), an SED panel (Surface-conduction Electron-emitter Display panel), or a CRT display panel (Cathode Ray Tube display panel).

The driving IC 30 may be arranged on the substrate 10, and may be arranged adjacent to the display panel 20. The driving IC 30 is to apply a driving signal and/or a data signal to the display panel 20, and may be arranged adjacent to the display panel 20.

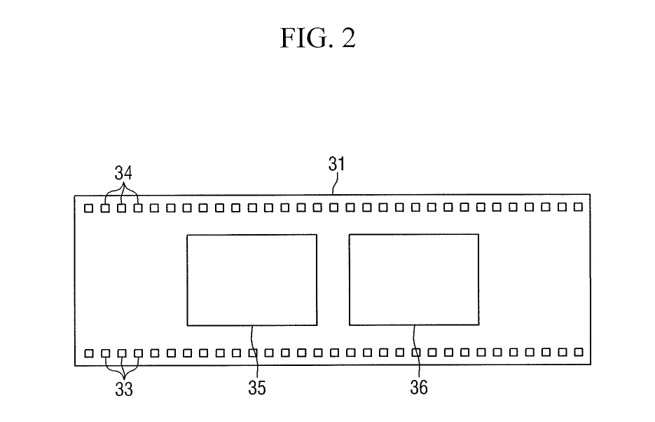

The driving IC 30 may include a gate driving IC 31 and a data driving IC 32. The gate driving IC 31 may mean an IC that applies a gate signal to the display panel 20 through a gate line of the display panel 20, and the data driving IC 32 may means an IC that applies a data signal to the display panel 20 through a data line of the display panel 20. FIG. 1 illustrates that the driving IC 30 is divided into the gate driving IC 31 and the data driving IC 32. However, since the gate driving IC 31 and the data driving IC 32 output different kinds of signals to the display panel 20, but have substantially the same configuration, both of them are hereinafter defined and described as the driving IC 30 having the same configuration. The driving IC 31 will be described in more detail with reference to FIG. 2.

FIG. 2 is a conceptual view of the driving IC 130 of a display device according to an embodiment. For convenience in explanation, the driving IC 30 is illustrated as the gate driving IC 31 in FIG. 2. The driving IC 30 may include an input pad 33, an output pad 34, a driving circuit unit 35, a memory 36, and a counter (which may be included in the memory 36).

The driving circuit unit 35 may include a gate driver, a source driver, an internal voltage generation unit, and a main logic unit as non-memory semiconductor devices.

The memory 36 may include a volatile memory and/or a nonvolatile memory. The memory 36 may include, for example, at least one register that is a volatile memory. Any one of the registers may be used as the counter. The counter may store numerical data, and the driving IC 30 may change the numerical data of the counter if a specified event that satisfies a predetermined condition occurs.

The memory 36 may include, for example, an OTP (One Time Programmable) memory or a MTP (Multi Time Programmable) memory, which is a nonvolatile memory.

The input pad 33 may be a pad for receiving an input signal from an external driving circuit unit (not illustrated) that controls the driving IC 30. The input signal received through the input pad 33 may be transferred to the driving circuit unit 35 or may be transferred to the memory 36. The output pad 34 may be a pad for applying a driving signal and/or a data signal to the display panel 20.

Hereinafter, the method of detecting an error in the display device 100 will be described based on the constituent elements of the display device 100.

The display device 100 may receive display data from an outside. The display data may be data that is used to display an image or a picture on the display panel 20.

Before the display device 100 receives the display data from the outside, the driving IC 30 may confirm numerical data stored in the counter. Thereafter, the display device 100 may receive the display data and a first error correction code (ECC) of the display data. The error correction code may be, for example, a parity code or a CRC (Cycle Redundancy Checking) code. The received display data and first error correction code may be stored in a register of the memory 36.

The driving IC 30 may generate a second error correction code based on the display data stored in the register. Thereafter, the driving IC 30 may compare the first error correction code stored in the register with the generated second error correction code.

If no error occurs in the process where the display device 100 receives the display data from the outside and stores the display data, the first error correction code and the second error correction code may be equal to each other. If an error occurs in the process where the display device 100 receives the display data from the outside, the first error correction code and the second error correction code may be different from each other.

If the first error correction code and the second error correction code are different from each other, the driving IC 30 may change the numerical data stored in the counter. For example, the driving IC 30 may increase the value of the numerical data stored in the counter.

The display device 100 may repeat the process of receiving the display data and the first error correction code of the display data from the outside. Further, if an error occurs in the process where the display device 100 receives the display data from the outside during repetition of the above-described process, the driving IC 30 may increase the value of the numerical data stored in the counter up to the frequency of the occurrence.

When the whole process of repeating the process of receiving the display data and the first error correction code of the display data from the outside is completed, the display device 100 may compare first numerical data stored in the counter before the display device 100 receives the display data from the outside with second numerical data stored after the whole receiving process is completed.

If no error has occurred while the display device 100 repeats the process of receiving the display data from the outside, the first numerical data and the second numerical data may be equal to each other. If an error has occurred while the display device 100 repeats the process of receiving the display data from the outside, the first numerical data and the second numerical data may be different from each other.

As described above, the result of comparing the numerical data stored in the counter before and after the display data is received from the outside may indicate whether the error occurs during the reception of the display data from the outside. Accordingly, the error can be detected based on the result of comparing the first numerical data with the second numerical data. In this case, a user or an inspector can detect the error occurrence by conforming only whether the numerical data stored in the counter is changed without the necessity of verifying individual bits of the display data that the display device 100 has received from the outside.

Partial data of the display data received by the display device 100 through the above-described process may be stored in the memory 36 of the driving IC 30. In particular, the data may be stored in the OTP memory or MTP memory of the memory 36. The display device 100 according to an embodiment may store in the memory 36 not only the display data that is the data used to display an image or a picture on the display panel 20, but also the first CRC (Cycle Redundancy Checking) code of the display data. The first CRC code may be received from the outside.

The CRC code may be used to determine whether the data stored in the memory 36 is accurately stored, that is, whether the data is stored without error. In this example embodiment, the CRC code is used. However, the error correction code is not limited thereto, i.e., various kinds of error correction codes may be used.

Once the display data and the first CRC code are stored in the memory 36, the driving IC 30, in particular, the driving circuit unit 35, may load the display data stored in the memory 36 and generate the second CRC code of the display data.

After generating the second CRC code, the driving IC 30 may compare the first CRC code with the second CRC code. As described above, the first CRC code is the CRC code of the display data before the display data is stored in the memory 36 and the second CRC code is the CRC code of the display data read from the memory 36 after the display data is stored in the memory 36. Accordingly, if the display data is stored in the memory 36 without error, the first CRC code and the second CRC code are equal and, if an error occurs when the display data is stored in the memory 36, the first CRC code and the second CRC code are different from each other. Accordingly, when the first CRC code and the second CRC code are different, the driving IC 30 may determine that the error has occurred.

The driving IC 30 may inscribe the result of the comparison of the first CRC code with the second CRC code in an error inscription register as an error flag. The error inscription register may be positioned in the memory 36 or may be positioned in the driving circuit unit 35. If the first CRC code and the second CRC code are different from each other as the result of the comparison of the first CRC code with the second CRC code, the driving IC 30 may inscribe the error flag. In some embodiments, if the first CRC code and the second CRC code are different from each other, the error flag may be set to “1”, and if the first CRC code and the second CRC code are equal to each other, the error flag may be set to “0”.

As described above, since the result of comparison of the first CRC code with the second CRC code indicates whether the error has occurred, the error can be detected based on the result of comparison of the first CRC code with the second CRC code. In this case, a user or an inspector may confirm whether the error has occurred by confirming only the value of the error flag inscribed in the error inscription register without the necessity of loading a display data mode stored in the memory 36. For example, as described above, under the assumption that if the first CRC code and the second CRC code are different from each other, the error flag is set to “1”, and if the first CRC code and the second CRC code are equal to each other, the error flag is set to “0”, the user or the inspector may determine that the error has occurred in the display data in the process of storing the data in the memory 36 if the value of the error flag confirmed by the user or the inspector is “1” and may determine that the error has not occurred in the display data in the process of storing the data in the memory 36 if the value of the error flag confirmed by the user or the inspector is “0”.

The display device 100 according to an embodiment can detect the error without verifying individual bits of the display data received from the outside. Verifying individual bits of the display data received from the outside to confirm whether the error has occurred requires a considerable amount of time. However, since the display device according to an embodiment can detect whether the error has occurred by confirming only whether the numerical data stored in the counter register has been changed without individually verifying bits of the received display data, the amount of time can be reduced or minimized.

In the display device according to an embodiment, the error can be detected without loading the whole display data stored in the memory. When loading the whole display data stored in the memory is required to confirm whether the error has occurred, a considerable loss of time may occur. However, the display device according to an embodiment compares only an error code, e.g., the CRC code value, without loading the whole display data stored in the memory, the loss of time that is required to confirm whether the error has occurred can be reduced or minimized. Further, since the user or the inspector can confirm whether the error has occurred by confirming only the error flag of the error inscription register without loading the whole display data stored in the memory, the loss of time can be minimized.

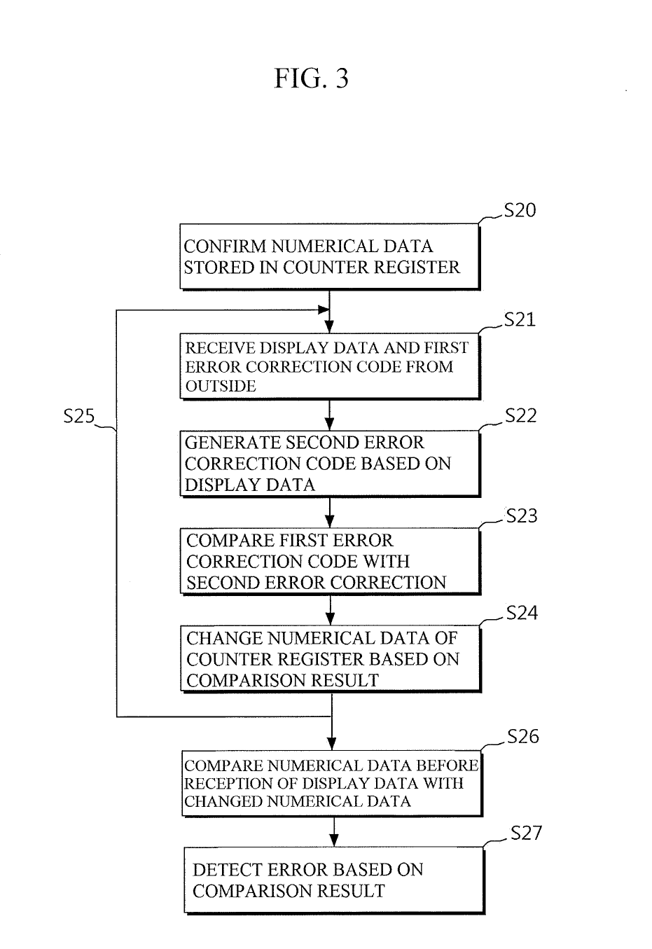

FIG. 3 is a flowchart illustrating a method of detecting an error in a display device according to an embodiment. FIG. 3 illustrates processes in which the display device 100 detects whether an error has occurred during reception of the display data from the outside.

First, a confirmation operation (S20) confirming the numerical data stored in the counter register may be performed. Next, a reception operation (S21) receiving the display data and the first error correction code of the display data from the outside may be performed. Next, a generation operation (S22) generating the second error correction code based on the received display data may be included. Since the method of generating the second error correction code is the same as described above, the description thereof will not be repeated.

Next, a first comparison operation (S23) comparing the received first error correction code with the generated second error correction code to provide a first comparison result may be included. Next, a changing operation (S24) changing the numerical data stored in the counter register based on the first comparison result may be included. Since the method of changing the numerical data is the same as described above, the description thereof will not be repeated.

Next, a repetition operation (S25) repeating the reception operation to the changing operation at least once may be included. However, the repetition operation (S25) may be omitted. Next, a second comparison operation (S26) comparing the numerical data stored in the counter register with the numerical data confirmed in the confirmation operation to provide a second comparison result may be included.

Next, a detection operation (S27) detecting the error based on the second comparison result may be included. However, the changing operation (S24) to the second comparison operation (S26) may be omitted. In this case, the detection operation (S27) may detect the error based on the first comparison result. Since the method of detecting the error is the same as described above, the description thereof will not be repeated.

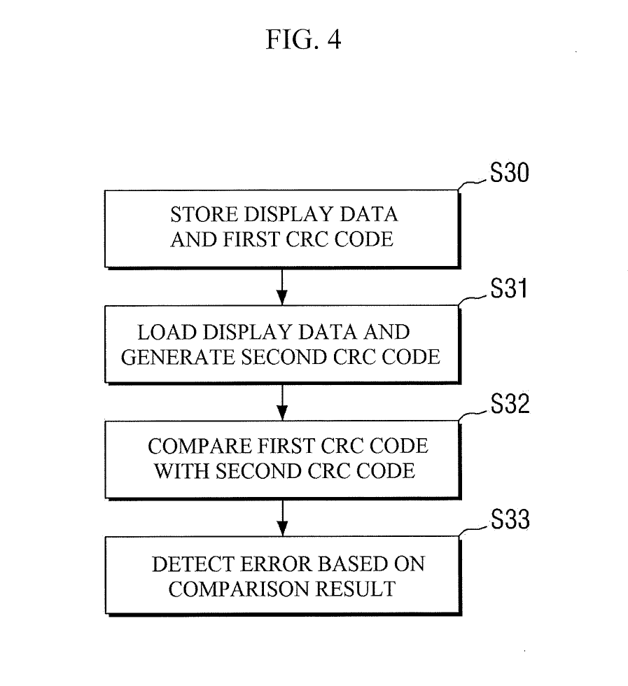

FIG. 4 is a flowchart illustrating a method of detecting an error in a display device according to an embodiment. FIG. 4 illustrates a process of detecting whether an error has occurred while the display data after detecting the error in the processes illustrated in FIG. 3 is stored in the OTP memory or the MTP memory of the memory 36.

First, the display data and the first CRC code of the display data are stored in the memory (S30). Since the storing of the display data and the first CRC code of the display data is substantially the same as the storing of the display data and the first CRC code illustrated in FIGS. 1 and 2, the duplicate description thereof will not be repeated.

Then, the second CRC code of the display data is generated by loading the display data stored in the memory (S31). The generation of the second CRC code may include the generation of the second CRC code inside the driving IC. Since the generation of the second CRC code is substantially the same as the generation of the second CRC code illustrated in FIGS. 1 and 2, the duplicate description thereof will be omitted.

Then, the first CRC code and the second CRC code are compared with each other (S32). Comparing the first CRC code with the second CRC code may include the comparing of the first CRC code with the second CRC code inside the driving IC. Further, comparing of the first CRC code with the second CRC code may include the inscribing the comparison result of the first CRC code with the second CRC code in the error inscription register as the error flag. Since comparing the first and second CRC codes with each other is substantially the same as comparing the first and second CRC codes with each other in FIGS. 1 and 2, the duplicate description thereof will not be repeated.

Then, the error is detected based on the result of the comparison of the first CRC code with the second CRC code (S33). Detecting of the error may include confirming whether the error has occurred during storing of the display data in the memory by confirming the error flag of the error inscription register. Detecting the error is substantially the same as detecting the error illustrated in FIGS. 1 and 2, the duplicate description thereof will not be repeated.

By way of summary and review, as described above, according to the method of detecting the error in the display device according to an embodiment, the error can be detected without loading the whole display data stored in the memory. In the case of loading the whole display data stored in the memory in order to confirm whether the error has occurred, a considerable loss of time may occur. However, the display device according to an embodiment compares only an error code, e.g., a CRC code, without loading the whole display data stored in the memory, the loss of time that is required to confirm whether the error has occurred can be reduced or minimized. Further, since the user or the inspector can confirm whether the error has occurred by confirming only the error flag of the error inscription register without loading the whole display data stored in the memory, the loss of time can be minimized.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A method of detecting an error in a display device including a memory and a driving IC on which the memory is arranged, the method comprising:
receiving display data and a first error correction code of the display data from an outside;
generating a second error correction code based on the received display data;
comparing the received first error correction code with the generated second error correction code to provide a first comparison result; and
detecting the error based on the first comparison result.

2. The method of detecting an error in a display device of claim 1, further comprising:
confirming numerical data stored in the memory before receiving display data and the first error correction code;
changing the numerical data stored in the memory based on the first comparison result; and
comparing the numerical data stored in the memory with confirmed numerical data for a second comparison result,
wherein detecting the error is based on the second comparison result.

3. The method of detecting an error in a display device of claim 2, further comprising repeating receiving to changing at least once after changing.

4. The method of detecting an error in a display device of claim 1, further comprising:
receiving a third error correction code of the display data after detecting and storing the display data and the third error correction code in the memory;
loading the display data stored in the memory and generating a fourth error correction code based on the loaded display data; and
comparing the third error correction code with the fourth error correction code for a third comparison result,
wherein detecting the error is based on the third comparison result.

5. A method of detecting an error in a display device including a memory and a driving IC on which the memory is arranged, the method comprising:
storing display data and a first CRC (Cycle Redundancy Checking) code of the display data in the memory;
loading the display data stored in the memory and generating a second CRC code of the display data;
comparing the first CRC code with the second CRC code to provide a comparison result; and
detecting the error based on the comparison result.

6. The method of detecting an error in a display device of claim 5, wherein:
the display device includes a display panel, and
the display data is data that is used to display an image or a picture on the display panel.

7. The method of detecting an error in a display device of claim 5, wherein generating comprises generating the second CRC code in an inside of the driving IC.

8. The method of detecting an error in a display device of claim 5, wherein comparing comprises comparing the first CRC code with the second CRC code in an inside of the driving IC.

9. The method of detecting an error in a display device of claim 5, wherein comparing comprises inscribing the result of the comparison of the first CRC code with the second CRC code in an error inscription register as an error flag.

10. The method of detecting an error in a display device of claim 9, wherein the error inscription register is included in the memory.

11. The method of detecting an error in a display device of claim 9, wherein detecting comprises confirming the error flag in the error inscription register.

12. The method of detecting an error in a display device of claim 5, wherein the memory is an OTP (One Time Programmable) memory or an MTP (Multi Time Programmable) memory.

13. A display device comprising a memory and a driving IC on which the memory is arranged, wherein the driving IC is configured to receive display data and a first error correction code of the display data from an outside, generate a second error correction code based on the received display data, compare the received first error correction code with the generated second error correction code to provide a first comparison result, and detect an error based on the first comparison result.

14. The display device of claim 13, wherein:
the numerical data is stored in the memory, and
the driving IC is configured to change the numerical data stored in the memory based on the first comparison result, compares the numerical data stored in the memory before receiving the display data with the numerical data changed on the basis of first comparison result to provide a second comparison result, and detect the error based on the second comparison result.

15. A display device comprising a memory and a driving IC on which the memory is arranged,
wherein display data and a first CRC (Cycle Redundancy Checking) code of the display data are stored in the memory, and
the driving IC is configured to load the display data stored in the memory, generate a second CRC code of the display data, compare the first CRC code with the second CRC code to generate a first comparison result, and detect the error based on the first comparison result.

16. The display device of claim 15, further comprising a display panel, wherein the display data is data that is used to display an image or a picture on the display panel.

17. The display device of claim 15, wherein the driving IC inscribes the result of the comparison of the first CRC code with the second CRC code in an error inscription register as an error flag.

18. The display device of claim 17, wherein the error inscription register is included in the memory.

19. The display device of claim 17, wherein the driving IC detects the error by confirming the error flag in the error inscription register.

20. The display device of claim 15, wherein the memory is an OTP (One Time Programmable) memory or an MTP (Multi Time Programmable) memory.
